(19) United States
(12) Patent Application Publication
(10) Pub. No.: US 2023/0307229 A1
(43) Pub. Date: Sep. 28, 2023

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Masaya NISHIDA, Toyama-shi (JP); Kotaro KONNO, Toyama-shi (JP); Ken IKETANI, Toyama-shi (JP)

(73) Assignee: Kokusai Electric Corporation, Tokyo (JP)

(21) Appl. No.: 18/172,772

(22) Filed: Feb. 22, 2023

(30) Foreign Application Priority Data
Mar. 24, 2022 (JP) 2022-048484

(51) Int. Cl. H01L 21/02; C23C 16/02; C23C 16/36; C23C 16/46; C23C 16/44; C23C 16/458

(52) U.S. Cl. CPC H01L 21/0228; C23C 16/0272; C23C 16/0227; C23C 16/36; C23C 16/46; C23C 16/4412; C23C 16/4584; H01L 21/022; H01L 21/0217; H01L 21/02167

(57) ABSTRACT

There is included (a) forming a first film having a predetermined composition on a first substrate by supplying a first processing gas to the first substrate; and (b) forming a second film having a composition different from the composition of the first film on the first substrate or a second substrate by performing a cycle including a supply of a second processing gas to the first substrate or the second substrate, wherein when performing (b) in a second state in which the second film adheres to an outermost surface of a member in the process container, the cycle is performed a predetermined m times, and wherein when performing (b) in a first state in which the first film adheres to the outermost surface, the cycle is performed m^{±} times, or the cycle is performed the m times after performing a precoating process of forming the second film.

### CROSS-REFERENCE TO RELATED APPLICATION

This application is based upon and claims the benefit of priority from Japanese Patent Application No. 2022-048484, filed on Mar. 24, 2022, the entire contents of which are incorporated herein by reference.

### TECHNICAL FIELD

The present disclosure relates to a method of processing a substrate, a method of manufacturing a semiconductor device, a substrate processing apparatus, and a recording medium.

### BACKGROUND

As a process for manufacturing a semiconductor device, a substrate processing process may be performed to form films having various compositions on a substrate accommodated in a process container.

### SUMMARY

Some embodiments of the present disclosure provide a technique capable of improving the controllability of the thickness of a film formed on a substrate.

According to one embodiment of the present disclosure, there is provided a technique that includes:
(a) forming a first film having a predetermined composition on a first substrate by supplying a first processing gas to the first substrate accommodated in a process container; and
(b) forming a second film having a composition different from the composition of the first film on the first substrate or a second substrate different from the first substrate by performing a cycle including a supply of a second processing gas to the first substrate or the second substrate which is accommodated in the process container,
wherein when performing (b) in a second state in which the second film adheres to an outermost surface of a member in the process container, the cycle is performed a predetermined m times, where m is an integer of 1 or more, and
wherein, when performing (b) in a first state in which the first film adheres to the outermost surface of the member in the process container, the cycle is performed m^{±} times, where m^{±} is an integer that is different from m, or the cycle is performed the m times after performing a precoating process of forming the second film on the outermost surface of the member in the process container.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which the portion of the process furnace 202 is illustrated in a vertical sectional view.

FIG. 2 is a schematic configuration diagram of the vertical process furnace of the substrate processing apparatus suitably used in embodiments of the present disclosure, in which the portion of the process furnace 202 is illustrated in a sectional view taken along line A-A in FIG. 1.

FIG. 3 is a schematic configuration diagram of a controller of the substrate processing apparatus suitably used in embodiments of the present disclosure, in which a control system of the controller 121 is illustrated in a block diagram.

FIG. 4 is a flowchart showing a gas supply sequence when forming a first film in embodiments of the present disclosure.

FIG. 5 is a flowchart showing a gas supply sequence when forming a second film in embodiments of the present disclosure.

FIG. 6 is a flowchart showing a control operation performed when forming a second film in embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

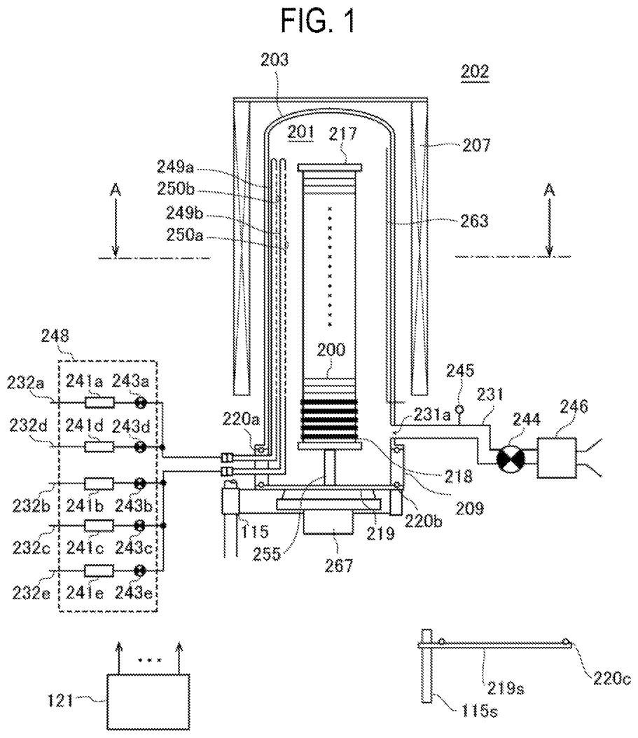

Hereinafter, embodiments of the present disclosure will be described mainly with reference to FIGS. 1 to 6. The drawings used in the following description are all schematic. The dimensional relationship of each element on the drawings, the ratio of each element, and the like do not always match the actual ones. Further, even between the drawings, the dimensional relationship of each element, the ratio of each element, and the like do not always match.

### (1) Configuration of Substrate Processing Apparatus

As shown in FIG. 1, a process furnace 202 includes a heater 207 as a heating mechanism (temperature adjuster). The heater 207 has a cylindrical shape and is vertically installed by being supported by a holding plate. The heater 207 also functions as an activation mechanism (excitation part) that activates (excites) a gas with heat.

Inside the heater 207, a reaction tube 203 is arranged concentrically with the heater 207. The reaction tube 203 is made of a heat-resistant material such as, for example, quartz (SiO₂) or silicon carbide (SiC), and is formed in a cylindrical shape with an upper end thereof closed and a lower end thereof opened. Below the reaction tube 203, a manifold 209 is arranged concentrically with the reaction tube 203. The manifold 209 is made of a metallic material such as stainless steel (SUS) or the like, and is formed in a cylindrical shape with upper and lower ends thereof opened. The upper end of the manifold 209 is engaged with the lower end of the reaction tube 203 and is configured to support the reaction tube 203. An O-ring 220a as a seal member is provided between the manifold 209 and the reaction tube 203. The reaction tube 203 is installed vertically just like the heater 207. A process container (reaction container) is mainly composed of the reaction tube 203 and the manifold 209. A process chamber 201 is formed in the hollow portion of the process container. The process chamber 201 is configured to accommodate wafers 200 as substrates. The wafers 200 are processed in the process chamber 201.

Nozzles 249a and 249b as a first supplier and a second supplier are installed in the process chamber 201 so as to penetrate the side wall of the manifold 209. The nozzles 249a and 249b are also referred to as a first nozzle and a second nozzle, respectively. The nozzles 249a and 249b are respectively made of a non-metallic material such as quartz or SiC, which is a heat-resistant material. Gas supply pipes 232a and 232b as a first pipe and a second pipe are connected to the nozzles 249a and 249b, respectively. The nozzles 249a and 249b are installed adjacent to each other.

Mass flow controllers (MFC) 241a and 241b as flow rate controllers (flow rate control parts) and valves 243a and 243b as opening/closing valves are installed in the gas supply pipes 232a and 232b sequentially from the upstream side of a gas flow. Gas supply pipes 232c and 232d are connected to the gas supply pipe 232a on the downstream side of the valve 243a. MFCs 241c and 241d and valves 243c and 243d are respectively installed in the gas supply pipes 232c and 232d sequentially from the upstream side of a gas flow. A gas supply pipe 232e is connected to the gas supply pipe 232b on the downstream side of the valve 243b. An MFC 241e and a valve 243e are installed in the gas supply pipe 232e sequentially from the upstream side of the gas flow. The gas supply pipes 232a to 232e are made of a metallic material such as stainless steel or the like.

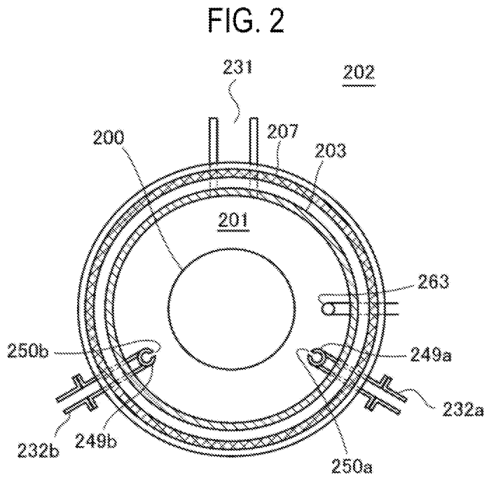

As shown in FIG. 2, the nozzles 249a and 249b are arranged in a space having an annular shape in a plan view between the inner wall of the reaction tube 203 and the wafers 200, and are installed to extend upward in the arrangement direction of the wafers 200 from the lower portion to the upper portion of the inner wall of the reaction tube 203. In other words, the nozzles 249a and 249b are respectively installed in a region horizontally surrounding a wafer arrangement region, in which the wafers 200 are arranged, on the lateral side of the wafer arrangement region so as to extend along the wafer arrangement region. Gas supply holes 250a and 250b for supplying gases are formed on the side surfaces of the nozzles 249a and 249b, respectively. The gas supply holes 250a and 250b are respectively opened so as to face the centers of the wafers 200 in a plan view and can supply gases toward the wafers 200. The gas supply holes 250a and 250b are formed from the lower portion to the upper portion of the reaction tube 203.

A precursor (precursor gas) as a processing gas (first processing gas or second processing gas) is supplied from the gas supply pipe 232a into the process chamber 201 via the MFC 241a, the valve 243a, and the nozzle 249a.

A nitrogen (N)-containing gas, which is a nitriding agent, as the processing gas (first processing gas or second processing gas) is supplied from the gas supply pipe 232b into the process chamber 201 via the MFC 241b, the valve 243b, and the nozzle 249b. The N-containing gas acts as an N source.

A nitrogen (N)- and carbon (C)-containing gas as the processing gas (first processing gas or second processing gas) is supplied from the gas supply pipe 232c into the process chamber 201 via the MFC 241c, the valve 243c, the gas supply pipe 232b, and the nozzle 249b. The N- and C-containing gas acts as a N source and a C source.

An inert gas is supplied from the gas supply pipes 232d and 232e into the process chamber 201 via the MFCs 241d and 241e, the valves 243d and 243e, the gas supply pipes 232a and 232b, and the nozzles 249a and 249b, respectively. The inert gas acts as a purge gas, a carrier gas, a diluting gas, or the like.

A processing gas supply system (first processing gas supply system or second processing gas supply system) is mainly constituted by the gas supply pipes 232a to 232c, the MFCs 241a to 241c, and the valves 243a to 243c. An inert gas supply system is mainly constituted by the gas supply pipes 232d and 232e, the MFCs 241d and 241e, and the valves 243d and 243e.

Some or all of the above-described various supply systems may be configured as an integrated supply system 248 in which the valves 243a to 243e, the MFCs 241a to 241e and the like are integrated. The integrated supply system 248 is connected to each of the gas supply pipes 232a to 232e and is configured so that the operations of supply of various gases into the gas supply pipes 232a to 232e, that is, the opening and closing operations of the valves 243a to 243e, the flow rate adjustment operation by the MFCs 241a to 241e, and the like are controlled by the controller 121 which will be described later. The integrated supply system 248 is formed of integral type or division type integrated units and may be attached to and detached from the gas supply pipes 232a to 232e and the like on an integrated unit basis. The integrated supply system 248 is configured so that the maintenance, replacement, expansion, and the like of the integrated supply system 248 can be performed on an integrated unit basis.

An exhaust port 231a for exhausting the atmosphere in the process chamber 201 is installed in the lower portion of the side wall of the reaction tube 203. The exhaust port 231a may be installed to extend from the lower portion to the upper portion of the side wall of the reaction tube 203, that is, along the wafer arrangement region. An exhaust pipe 231 is connected to the exhaust port 231a. The exhaust pipe 231 is made of a metallic material such as stainless steel or the like. A vacuum pump 246 as an exhaust device is connected to the exhaust pipe 231 via a pressure sensor 245 as a pressure detector (pressure detection part) for detecting the pressure inside the process chamber 201 and an APC (Auto Pressure Controller) valve 244 as a pressure regulator (pressure regulation part). The APC valve 244 is configured so that it can perform or stop vacuum exhaust of the interior of the process chamber 201 by being opened and closed in a state in which the vacuum pump 246 is operated. Furthermore, the APC valve 244 is configured so that it can regulate the pressure inside the process chamber 201 by adjusting the valve opening degree based on the pressure information detected by the pressure sensor 245 in a state in which the vacuum pump 246 is operated. An exhaust system is mainly constituted by the exhaust pipe 231, the APC valve 244 and the pressure sensor 245. The vacuum pump 246 may be included in the exhaust system.

A seal cap 219 as a furnace opening lid capable of airtightly closing the lower end opening of the manifold 209 is installed below the manifold 209. The seal cap 219 is made of a metallic material such as, for example, stainless steel or the like, and is formed in a disc shape. On the upper surface of the seal cap 219, there is installed an O-ring 220b as a seal member which abuts against the lower end of the manifold 209. Below the seal cap 219, there is installed a rotator 267 for rotating a boat 217 to be described later. A rotating shaft 255 of the rotator 267 is made of, for example, a metallic material such as stainless steel or the like and is connected to the boat 217 through the seal cap 219. The rotator 267 is configured to rotate the wafers 200 by rotating the boat 217. The seal cap 219 is configured to be raised and lowered in the vertical direction by a boat elevator 115 as an elevating mechanism installed outside the reaction tube 203. The boat elevator 115 is configured as a transfer system (transfer mechanism) that loads and unloads (transfers) the wafers 200 into and out of the process chamber 201 by raising and lowering the seal cap 219.

Below the manifold 209, a shutter 219s is installed as a furnace opening lid capable of airtightly closing the lower end opening of the manifold 209 in a state in which the seal cap 219 is lowered and the boat 217 is unloaded from the process chamber 201. The shutter 219s is made of a metallic material such as stainless steel or the like and is formed in a disk shape. An O-ring 220c as a seal member that comes into contact with the lower end of the manifold 209 is installed on the upper surface of the shutter 219s. The opening/closing operations (the elevating operation, the rotating operation, and the like) of the shutter 219s are controlled by a shutter opener/closer 115s.

A boat 217 as a substrate support tool is configured so as to support a plurality of wafers 200, for example, 25 to 200 wafers 200 in a horizontal posture and in multiple stages while vertically arranging the wafers 200 with the centers thereof aligned with each other, that is, so as to arrange the wafers 200 at intervals. The boat 217 is made of a heat-resistant material such as, for example, quartz or SiC. Heat insulating plates 218 made of a heat-resistant material such as, for example, quartz or SiC, are supported in multiple stages at the bottom of the boat 217.

Inside the reaction tube 203, there is installed a temperature sensor 263 as a temperature detector. By adjusting a state of supplying electric power to the heater 207 based on the temperature information detected by the temperature sensor 263, the temperature inside the process chamber 201 becomes a desired temperature distribution. The temperature sensor 263 is installed along the inner wall of the reaction tube 203.

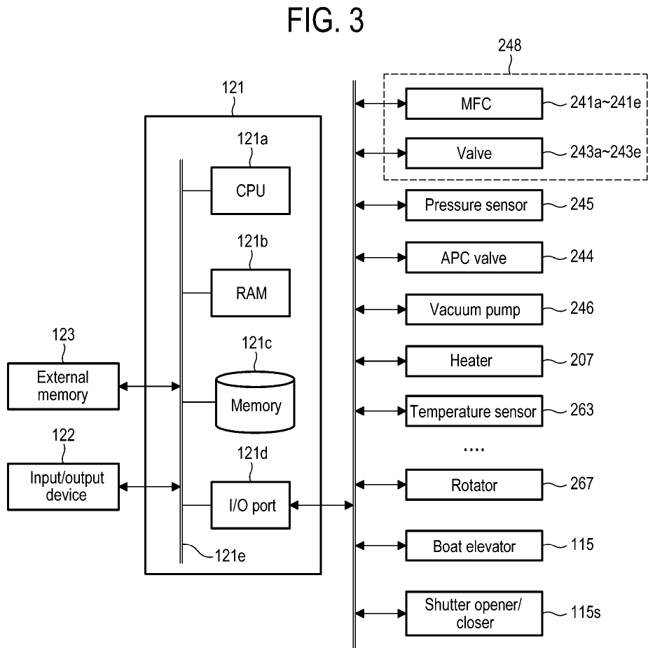

As shown in FIG. 3, the controller 121 as a control part (control means) is configured as a computer including a CPU (Central Processing Unit) 121a, a RAM (Random Access Memory) 121b, a memory 121c and an I/O port 121d. The RAM 121b, the memory 121c and the I/O port 121d are configured to exchange data with the CPU 121a via an internal bus 121e. An input/output device 122 configured as, for example, a touch panel or the like is connected to the controller 121.

The memory 121c is composed of, for example, a flash memory, an HDD (Hard Disk Drive), an SSD (Solid State Drive), or the like. In the memory 121c, there are readably stored a control program for controlling the operation of the substrate processing apparatus, a process recipe in which procedures and conditions of substrate processing to be described later are written, and the like. The process recipe is a combination for causing the controller 121 to execute the respective procedures in a below-described substrate processing process so as to obtain a predetermined result. The process recipe functions as a program. Hereinafter, the control program, the process recipe and the like are collectively and simply referred to as a program. Furthermore, the process recipe is also simply referred to as a recipe. When the term “program” is used herein, it may means a case of including only the recipe, a case of including only the control program, or a case of including both the recipe and the control program. The RAM 121b is configured as a memory area (work area) in which programs, data and the like read by the CPU 121a are temporarily held.

The I/O port 121d is connected to the MFCs 241a to 241e, the valves 243a to 243e, the pressure sensor 245, the APC valve 244, the vacuum pump 246, the temperature sensor 263, the heater 207, the rotator 267, the boat elevator 115, the shutter opener/closer 115s, and the like.

The CPU 121a is configured to read and execute the control program from the memory 121c and to read the recipe from the memory 121c in response to an input of an operation command from the input/output device 122 or the like. The CPU 121a is configured to, according to the contents of the recipe thus read, control the flow rate adjustment operation of various gases by the MFCs 241a to 241e, the opening/closing operations of the valves 243a to 243e, the opening/closing operation of the APC valve 244, the pressure regulation operation by the APC valve 244 based on the pressure sensor 245, the start and stop of the vacuum pump 246, the temperature adjustment operation of the heater 207 based on the temperature sensor 263, the rotation and the rotation speed adjustment operation of the boat 217 by the rotator 267, the raising and lowering operation of the boat 217 by the boat elevator 115, the opening/closing operation of the shutter 219s by the shutter opener/closer 115s, and the like.

The controller 121 may be configured by installing, in the computer, the above-described program stored in an external memory 123. The external memory 123 includes, for example, a magnetic disk such as an HDD or the like, an optical disk such as a CD or the like, a magneto-optical disk such as an MO or the like, a semiconductor memory such as a USB memory, an SSD or the like, and so forth. The memory 121c and the external memory 123 are configured as a computer readable recording medium. Hereinafter, the memory 121c and the external memory 123 are collectively and simply referred to as a recording medium. As used herein, the term “recording medium” may include only the memory 121c, only the external memory 123, or both. The provision of the program to the computer may be performed by using a communication means such as the Internet or a dedicated line without having to use the external memory 123.

### (2) Substrate Processing Process

As a process of manufacturing a semiconductor device using the substrate processing apparatus described above, there may be performed a process (hereinafter also referred to as first film formation) in which a first processing gas is supplied to a wafer 200 as a substrate accommodated in a process container to form a first film having a predetermined composition on the wafer 200. In addition, there may be performed a process (hereinafter also referred to as second film formation) in which a cycle of supplying a second processing gas to the wafer 200 accommodated in the process container is performed to form a second film having a composition different from the composition of the first film on the wafer 200. Moreover, there may be performed a process (precoating) in which a film having a predetermined composition is formed on the outermost surface of a member in the process container in a state in which the wafer 200 is not present in the process container.

Specific contents of the first film formation, the second film formation, and the precoating will be described below. In the following description, the operation of each part constituting the substrate processing apparatus is controlled by the controller 121.

When the term “wafer” is used herein, it may refer to “a wafer itself” or “a laminated body of a wafer and a predetermined layer or film formed on the surface of the wafer.” When the phrase “a surface of a wafer” is used herein, it may refer to “a surface of a wafer itself” or “a surface of a predetermined layer or the like formed on a wafer.” When the expression “a predetermined layer is formed on a wafer” is used herein, it may mean that “a predetermined layer is directly formed on a surface of a wafer itself” or that “a predetermined layer is formed on a layer or the like formed on a wafer.” When the term “substrate” is used herein, it may be synonymous with the term “wafer.”

### <<First Film Formation>>

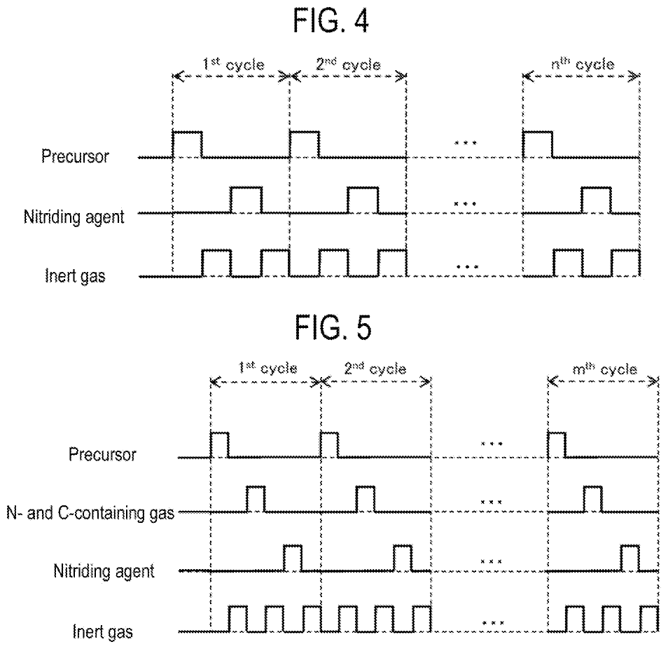

First, the processing procedure and processing conditions of first film formation will be described with reference to FIG. 4. In the following, as an example, a case where a first film-forming process is newly started without loading the wafer 200 into the process container will be described.

In the present embodiment, in the first film-forming process, for example, a precursor and a nitriding agent may be supplied as a first processing gas to form a first film having a predetermined composition on the wafer 200.

In the first film-forming process according to the present embodiment, as in the processing sequence shown in FIG. 4, a first film having a predetermined composition is formed on the wafer 200 by performing a cycle a predetermined number of times (n times where n is an integer of 1 or more), the cycle including non-simultaneously performing:
step A1 of supplying a precursor to the wafer 200 accommodated in the process container; and
step A2 of supplying a nitriding agent to the wafer 200 accommodated in the process container.

In this specification, the processing sequence described above may also be denoted as follows for the sake of convenience. The same notation is used also in the following description of other embodiments, modifications, and the like.

(precursor→nitriding agent)×n

### (Wafer Charging)

A plurality of wafers 200 is charged into the boat 217 (wafer charging). Thereafter, the shutter 219s is moved by the shutter opener/closer 115s to open the lower end opening of the manifold 209 (shutter opening). The wafers 200 include product wafers and dummy wafers.

### (Boat Loading)

Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b.

### (Pressure Regulation and Temperature Adjustment)

After the boat loading is completed, the inside of the process chamber 201, that is, the space where the wafer 200 exists, is vacuum-exhausted (decompression-exhausted) by the vacuum pump 246 so that the pressure inside the process chamber 201 becomes a desired pressure (degree of vacuum). At this time, the pressure inside the process chamber 201 is measured by the pressure sensor 245, and the APC valve 244 is feedback-controlled based on the measured pressure information (pressure regulation). Furthermore, the wafer 200 in the process chamber 201 is heated by the heater 207 so that the wafer 200 has a desired processing temperature. At this time, the state of supplying electric power to the heater 207 is feedback-controlled based on the temperature information detected by the temperature sensor 263 so that the inside of the process chamber 201 has a desired temperature distribution (temperature adjustment). Moreover, the rotation of the wafer 200 by the rotator 267 is started. The exhaust of the process chamber 201 and the heating and rotation of the wafer 200 are continuously performed at least until the processing on the wafer 200 is completed.

### (Gas Supply Cycle)

Thereafter, steps A1 and A2 are sequentially performed.

### [Step A1]

In step A1, a precursor (precursor gas) is supplied to the wafer 200 in the process chamber 201.

Specifically, the valve 243a is opened to allow the precursor to flow into the gas supply pipe 232a. The flow rate of the precursor is adjusted by the MFC 241a. The precursor is supplied into the process chamber 201 via the nozzle 249a, and is exhausted from the exhaust port 231a. At this time, the precursor is supplied to the wafer 200 from the lateral side of the wafer 200 (precursor supply). At this time, the valves 243d and 243e may be opened to supply an inert gas into the process chamber 201 via each of the nozzles 249a and 249b.

An example of a processing condition in this step is described as follows.

Processing temperature: 550 to 800 degrees C., specifically 550 to 650 degrees C.

Processing pressure: 1 to 2,666 Pa, specifically 67 to 931 Pa

Precursor supply flow rate: 0.01 to 2 slm, specifically 0.1 to 1 slm

Precursor supply time: 1 to 20 seconds, specifically 1 to 10 seconds

Inert gas supply flow rate (for each gas supply pipe): 0 to 10 slm

In this specification, the expression of a numerical range such as “550 to 800 degrees C.” means that the lower limit and the upper limit of the numerical range are included in the range. Therefore, for example, “550 to 800 degrees C.” means “550 degrees C. or higher and 800 degrees C. or lower”. The same applies to other numerical ranges. Further, the processing temperature in this specification means the temperature of the wafer 200 or the temperature inside the process chamber 201, and the processing pressure means the pressure inside the process chamber 201. In addition, the gas supply flow rate of 0 slm means a case where the gas is not supplied. These also apply to the following description.

By supplying, for example, a chlorosilane-based gas as a precursor to the wafer 200 under the above-described processing condition, a Si-containing layer containing Cl is formed on the outermost surface of the wafer 200 as a base. The Si-containing layer containing Cl is formed on the outermost surface of the wafer 200 by the physical adsorption or chemical adsorption of molecules of a chlorosilane-based gas, the physical adsorption or chemical adsorption of molecules of a substance obtained by partially decomposing a chlorosilane-based gas, the deposition of Si through thermal decomposition of a chlorosilane-based gas, or the like. The Si-containing layer containing C1 may be an adsorption layer (physical adsorption layer or chemical adsorption layer) of molecules of a chlorosilane-based gas or a substance obtained by partially decomposing the chlorosilane-based gas, or may be a Si deposition layer containing Cl. In this specification, the Si-containing layer containing Cl is also simply referred to as Si-containing layer. Under the above-described processing condition, the physical adsorption or chemical adsorption of the molecules of the chlorosilane-based gas or the molecules of the substance obtained by partially decomposing the chlorosilane-based on the outermost surface of the wafer 200 occurs dominantly (preferentially). The deposition of Si through thermal decomposition of the chlorosilane-based gas occurs slightly or hardly occurs. That is, under the above-described processing condition, the Si-containing layer contains an overwhelmingly large amount of adsorption layer (physisorption layer or chemisorption layer) of the molecules of chlorosilane-based gas or the molecules of the substance obtained by partially decomposing the chlorosilane-based gas. The Si-containing layer contains a small amount of Si deposition layer containing Cl or hardly contains the Si deposition layer containing Cl.

After the Si-containing layer is formed, the valve 243a is closed to stop the supply of the precursor into the process chamber 201. Then, the inside of the process chamber 201 is exhausted to remove the gas or the like remaining in the process chamber 201 from the inside of the process chamber 201 (purging). At this time, the valves 243d and 243e are opened to supply an inert gas into the process chamber 201. The inert gas acts as a purge gas.

An example of a processing condition in the purging is described as follows.

Inert gas supply flow rate (for each gas supply pipe): 1 to 20 slm

Inert gas supply time: 1 to 20 seconds, specifically 1 to 10 seconds

Other processing conditions are the same as the processing conditions when supplying the precursor in this step.

As the precursor, for example, a silane-based gas containing silicon (Si) as a main element constituting the film to be formed on the wafer 200 may be used. As the silane-based gas, for example, a gas containing halogen and Si, that is, a halosilane-based gas may be used. Halogen includes chlorine (Cl), fluorine (F), bromine (Br), iodine (I), and the like. As the halosilane-based gas, for example, the above-described chlorosilane-based gas containing Cl and Si may be used.

As the precursor, for example, a chlorosilane-based gas such as a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄, abbreviation: 4CS) gas, a hexachlorodisilane (Si₂Cl₆, abbreviation: HCDS) gas, an octachlorotrisilane (Si₃Cl₈, abbreviation: OCTS) gas, or the like may be used. One or more of these gases may be used as the precursor.

As the precursor, in addition to the chlorosilane-based gas, a fluorosilane-based gas such as tetrafluorosilane (SiF₄) gas, a difluorosilane (SiH₂F₂) gas or the like, a bromosilane-based gas such as a tetrabromosilane (SiBr₄) gas, a dibromosilane (SiH₂Br₂) gas or the like, and an iodosilane-based gas such as a tetraiodosilane (SiI₄) gas, a diiodosilane (SiH₂I₂) gas or the like may also be used. One or more of these gases may be used as the precursor.

As the precursor, in addition to these gases, for example, a gas containing an amino group and Si, i.e., an aminosilane-based gas may also be used. The amino group is a monovalent functional group obtained by removing hydrogen (H) from ammonia, primary amine, or secondary amine, and may be expressed as —NH₂, —NHR, or —NR₂. R represents an alkyl group, and two R's in —NR₂ may be the same or different.

As the precursor, for example, an aminosilane-based gas such as a tetrakis(dimethylamino)silane (Si[N(CH₃)₂]₄, abbreviation: 4DMAS) gas, a tris(dimethylamino)silane (Si[N(CH₃)₂]₃H, abbreviation: 3DMAS) gas, a bis(diethylamino)silane (Si[N(C₂H₅)₂]₂₂, abbreviation: BDEAS) gas, a bis(tert-butylamino)silane (SiH₂[NH(C₄H₉)]₂, abbreviation: BTBAS) gas, a (diisopropylamino)silane (SiH₃[N(C₃H₇)₂], abbreviation: DIPAS) gas, or the like may also be used. One or more of these gases may be used as precursor. These points are the same in steps B1 and C1, which will be described later.

As the inert gas, for example, a nitrogen (N₂) gas, or a rare gas such as an argon (Ar) gas, a helium (He) gas, a neon (Ne) gas, a xenon (Xe) gas, a krypton (Kr) gas, a radon (Rn) gas or the like may be used. One or more of these gases may be used as the inert gas. This point holds true in each step described later.

### [Step A2]

After step A1 is completed, a nitriding agent is supplied to the wafer 200 in the process chamber 201, that is, the Si-containing layer formed on the wafer 200.

Specifically, the valve 243b is opened to allow the nitriding agent to flow into the gas supply pipe 232b. The flow rate of the nitriding agent is adjusted by the MFC 241b. The nitriding agent is supplied into the process chamber 201 via the nozzle 249b, and is exhausted from the exhaust port 231a. At this time, the nitriding agent is supplied to the wafer 200 from the lateral side of the wafer 200 (nitriding agent supply). At this time, the valves 243d and 243e may be opened to supply an inert gas into the process chamber 201 via each of the nozzles 249a and 249b.

An example of a processing condition in this step is described as follows.

Processing pressure: 1 to 4,000 Pa, specifically 1 to 1,200 Pa

Nitriding agent supply flow rate: 0.1 to 20 slm, specifically 1 to 10 slm

Nitriding agent supply time: 1 to 120 seconds, specifically 1 to 60 seconds

Other processing conditions are the same as the processing conditions when supplying the precursor in step A1.

At least a portion of the Si-containing layer formed on the wafer 200 is nitrided (modified) by supplying the nitriding agent to the wafer 200 under the above-described processing condition. As a result, a silicon nitride layer (SiN layer) is formed as a layer containing Si and N on the outermost surface of the wafer 200 as a base. When forming the SiN layer, impurities such as Cl and the like contained in the Si-containing layer form a gaseous substance containing at least Cl in the course of the modifying reaction for the Si-containing layer by the nitriding agent. The gaseous substance is discharged from the process chamber 201. As a result, the SiN layer becomes a layer containing fewer impurities such as Cl and the like than the Si-containing layer formed in step A1.

After the SiN layer is formed, the valve 243b is closed to stop the supply of the nitriding agent into the process chamber 201. The gas and the like remaining in the process chamber 201 are removed from the inside of the process chamber 201 by the same processing procedure as in the purging in step A1 (purging).

As the nitriding agent, for example, an N- and H-containing gas may be used. It is desirable that the nitriding agent has an N—H bond. As the nitriding agent, for example, a hydrogen nitride-based gas such as an ammonia (NH₃) gas, a diazene (N₂H₂) gas, a hydrazine (N₂H₄) gas, an N₃H₈ gas, or the like may be used. One or more of these gases may be used as the nitriding agent. This point also applies to steps B3 and C3, which will be described later.

### [Performing a Predetermined Number of Times]

A cycle of performing the above-described steps A1 and A2 non-synchronously, that is, without synchronization, is performed a predetermined number of times (n times where n is an integer of 1 or more), whereby a first film, for example, a silicon nitride film (SiN film) having a predetermined thickness and containing Si as a first element and N as a second element can be formed on the surface of the wafer 200 as a base. It is desirable that the above-mentioned cycle is repeated multiple times. That is, it is desirable that the thickness of the SiN layer formed per cycle is set to be smaller than a desired film thickness, and the above-mentioned cycle is repeated multiple times until the thickness of a SiN film formed by stacking the SiN layers reaches the desired film thickness.

### (After-Purging and Atmospheric Pressure Restoration)

After completing the process of forming the first nitride film having a desired thickness on the wafer 200, an inert gas as a purge gas is supplied into the process chamber 201 from each of the nozzles 249a and 249b, and is exhausted from the exhaust port 231a. As a result, the inside of the process chamber 201 is purged, and the gas, reaction by-products and the like remaining in the process chamber 201 are removed from the inside of the process chamber 201 (after-purging). Thereafter, the atmosphere in the process chamber 201 is replaced with the inert gas (inert gas replacement), and the pressure in the process chamber 201 is restored to the atmospheric pressure (atmospheric pressure restoration).

### (Boat Unloading)

Thereafter, the seal cap 219 is lowered by the boat elevator 115 to open the lower end of the manifold 209. Then, the processed wafers 200 supported by the boat 217 are unloaded from the lower end of the manifold 209 to the outside of the reaction tube 203 (boat unloading). After the boat is unloaded, the shutter 219s is moved and the lower end opening of the manifold 209 is sealed by the shutter 219s via the O-ring 220c (shutter closing).

### (Wafer Cooling)

After unloading the boat, that is, after closing the shutter, the processed wafers 200 are cooled down to a predetermined temperature at which they can be taken out, while being supported by the boat 217 (wafer cooling).

### (Wafer Discharging)

After cooling the wafers, the processed wafers 200 that have been cooled to the predetermined temperature at which they can be taken out are discharged from the boat 217 (wafer discharging).

Thus, a series of processes for forming the first film on the wafer 200 is completed.

### <<Second Film Formation>>

Next, the processing procedure and processing conditions of the second film formation will be described with reference to FIG. 5. A case where a second film-forming process is newly started in a state in which the wafer 200 is not loaded into the process container will be described below.

In the present embodiment, in the second film-forming process, for example, a precursor, an N- and C-containing gas, and a nitriding agent are supplied as a second processing gas, whereby a second film having a composition different from the composition of the first film can be formed on the wafer 200.

In the second film-forming process according to the present embodiment, as in the processing sequence shown in FIG. 5, a second film having a composition different from the composition of the first film is formed on the wafer 200 by performing a cycle a predetermined number of times (m times where m is an integer of 1 or more), the cycle including non-simultaneously performing:
step B1 of supplying a precursor to the wafer 200 accommodated in the process container;
step B2 of supplying an N- and C-containing gas to the wafer 200 accommodated in the process container; and
step B3 of supplying a nitriding agent to the wafer 200 accommodated in the process container.

In this specification, the processing sequence described above may also be denoted as follows for the sake of convenience. The same notation is used also in the following description of other embodiments, modifications, and the like.

(precursor→N- and C-containing gas→nitriding agent)×m

First, wafer charging, boat loading, and pressure regulation/temperature adjustment are performed by the same procedure as the wafer charging, the boat loading, and the pressure regulation/temperature adjustment in the above-described first film formation.

### (Gas Supply Cycle)

Thereafter, steps B1 and B2 are sequentially performed.

### [Step B1]

In step B1, a precursor is supplied to the wafer 200 in the process chamber 201 according to the same processing procedures and processing conditions as those in step A1 (precursor supply). Thus, a Si-containing layer is formed on the outermost surface of the wafer 200. After the Si-containing layer is formed, the supply of the precursor into the process chamber 201 is stopped, and the gas and the like remaining in the process chamber 201 are removed from the inside of the process chamber 201 by the same processing procedure as the purging in step A1 (purging).

### [Step B2]

After step B1 is completed, an N- and C-containing gas is supplied to the wafer 200 in the process chamber 201, that is, the Si-containing layer formed on the wafer 200.

Specifically, the valve 243c is opened to allow the N- and C-containing gas to flow into the gas supply pipe 232c. The flow rate of the N- and C-containing gas is adjusted by the MFC 241c. The N- and C-containing gas is supplied into the process chamber 201 via the nozzle 249b, and exhausted from the exhaust port 231a. At this time, the N- and C-containing gas is supplied to the wafer 200 from the lateral side of the wafer 200 (N- and C-containing gas supply). At this time, the valves 243d and 243e may be opened to supply an inert gas into the process chamber 201 via each of the nozzles 249a and 249b.

An example of a processing condition in this step is described as follows.

Processing pressure: 1 to 4,000 Pa, specifically 1 to 1,200 Pa

N- and C-containing gas supply flow rate: 0.1 to 1 slm

N- and C-containing gas supply time: 1 to 120 seconds, specifically 1 to 60 seconds

Other processing conditions are the same as the processing conditions when supplying the precursor in step A1.

At least a portion of the Si-containing layer formed on the wafer 200 is modified by supplying, for example, an N- and C-containing gas to the wafer 200 under the above-described condition. As a result, a silicon carbonitride layer (SiCN layer) as a layer containing Si, C, and N is formed on the outermost surface of the wafer 200 as a base. When forming the SiCN layer, impurities such as Cl and the like contained in the Si-containing layer form a gaseous substance containing at least Cl in the course of the modifying reaction of the Si-containing layer by the N-and C-containing gas. The gaseous substance is discharged from the process chamber 201. As a result, the SiCN layer becomes a layer containing fewer impurities such as Cl and the like than the Si-containing layer formed in step B1.

After the SiCN layer is formed, the valve 243c is closed to stop the supply of the N- and C-containing gas into the process chamber 201, and the gas and the like remaining in the process chamber 201 are removed from the inside of the process chamber 201 by the same procedure as in the purging in step A1 (purging).

As the N- and C-containing gas, for example, an ethylamine-based gas such as a monoethylamine (C₂H₅NH₂, abbreviation: ME A) gas, a diethylamine ((C₂H₅)₂NH, abbreviation: DEA) gas, a triethylamine ((C₂H₅)₃N, abbreviation: TEA) gas or the like, a methylamine-based gas such as a monomethylamine (CH₃NH₂, abbreviation: MMA) gas, a dimethylamine ((CH₃)₂NH, abbreviation: DMA) gas, a trimethylamine ((CH₃)₃N, abbreviation: TMA) gas or the like, and an organic hydrazine-based gas such as a monomethylhydrazine ((CH₃)HN₂H₂, abbreviation: MMH) gas, a dimethylhydrazine ((CH₃)₂N₂H₂, abbreviation: DMH) gas, a trimethylhydrazine ((CH₃)₂N₂(CH₃)H, abbreviation: TMH) gas or the like may be used. One or more of these gases may be used as the N- and C-containing gas. This point also applies to step C2, which will be described later.

### [Step B3]

After step B2 is completed, a nitriding agent is supplied to the wafer 200 in the process chamber 201, that is, the SiCN layer formed on the wafer 200 by the same processing procedure and processing conditions as the processing procedure and processing conditions in step A2 described above (nitriding agent supply). As a result, by further introducing a N component into the SiCN layer formed on the wafer 200, this layer can be modified into a SiCN layer with a higher N concentration. After the SiCN layer is modified, the supply of the nitriding agent into the process chamber 201 is stopped, and the gas and the like remaining in the process chamber 201 are removed from the process chamber 201 by the same processing procedure as in the purging in step A1 (purging).

### [Performing a Predetermined Number of Times]

A cycle of performing the above-described steps B1 to B3 non-simultaneously, that is, without synchronization is performed a predetermined number of times (m times where m is an integer of 2 or more), whereby a second film, for example, a silicon carbonitride film (SiCN film) having a predetermined thickness and containing Si as a first element, N as a second element, and C as a third element can be formed on the surface of the wafer 200 as a base. It is desirable that the above-mentioned cycle is repeated multiple times. That is, it is desirable that the thickness of the SiCN layer formed per cycle is set to be smaller than a desired film thickness, and the above-mentioned cycle is repeated multiple times until the thickness of a SiCN film formed by stacking the SiCN layers reaches the desired film thickness.

Thereafter, after-purging/atmospheric pressure restoration, boat unloading, wafer cooling, and wafer discharging are performed by the same processing procedure as in the after-purging/atmospheric pressure restoration, the boat unloading, the wafer cooling, and the wafer discharging in the above-described first film formation.

Thus, a series of processes for forming the second film on the wafer 200 is completed.

### <<Precoating>>

Next, the processing procedure and processing conditions of precoating will be described. A case where the second film is formed on the outermost surface of a member in the process container in a state in which the wafer 200 is not loaded into the process container will be described.

In the present embodiment, in the precoating, for example, a precursor, which serve as a second processing gas, an N- and C-containing gas, and a nitriding agent may be supplied to form a second film on the outermost surface of a member in the process container.

In the precoating according to the present embodiment, as in the processing sequence shown in FIG. 5, a second film is formed on the outermost surface of a member in the process container by performing a cycle a predetermined number of times (1 times where 1 is an integer of 1 or more), the cycle including non-simultaneously performing:
step C1 of supplying the precursor into the process container;
step C2 of supplying the N- and C-containing gas into the process container; and
step C3 of supplying the nitriding agent into the process container.

In this specification, the processing sequence described above may also be denoted as follows for the sake of convenience. The same notation is used also in the following description of other embodiments, modifications, and the like.

(precursor→N- and C-containing gas→nitriding agent)×1

An empty boat 217, that is, a boat 217 holding no wafers 200 is raised by the boat elevator 115 and loaded into the process chamber 201 (empty boat loading). Thereafter, pressure regulation/temperature adjustment is performed by the same procedure as the pressure regulation/temperature adjustment in the above-described first film formation. The boat 217 does not have to be rotated during the precoating.

### (Gas Supply Cycle)

Thereafter, steps C1 to C3 are sequentially performed.

### [Step C1]

In step C1, a precursor is supplied into the process container according to the same processing procedure and processing conditions as those in step A1 described above (precursor supply). Thus, a Si-containing layer is formed on the outermost surface of the member in the process container. After the Si-containing layer is formed, the supply of the precursor into the process chamber 201 is stopped, and the gas and the like remaining in the process chamber 201 are removed from the inside of the process chamber 201 by the same processing procedure as in the purging in step A1 (purging).

### [Step C2]

After step C1 is completed, an N- and C-containing gas is supplied into the process container according to the same processing procedure and processing conditions as those in step B2 described above (N- and C-containing gas supply). Thus, at least a portion of the Si-containing layer formed on the outermost surface of the member in the process container is modified. As a result, a silicon carbonitride layer (SiCN layer) as a layer containing Si, C, and N is formed on the outermost surface of the member in the process container. When forming the SiCN layer, impurities such as Cl and the like contained in the Si-containing layer form a gaseous substance containing at least Cl in the course of the modifying reaction of the Si-containing layer by the N- and C-containing gas. The gaseous substance is discharged from the inside of the process chamber 201. As a result, the SiCN layer becomes a layer containing fewer impurities such as Cl and the like than the Si-containing layer formed in step Cl.

### [Step C3]

After step C2 is completed, a nitriding agent is supplied into the process container according to the same processing procedure and processing conditions as those in step A2 described above (nitriding agent supply). As a result, by further introducing a N component into the SiCN layer formed on the outermost surface of the member in the process container, it is possible to modify this layer into a SiCN layer having a higher N concentration. After the SiCN layer is modified, the supply of the nitriding agent into the process chamber 201 is stopped, and the gas and the like remaining in the process chamber 201 are removed from the inside of the process chamber 201 by the same processing procedure as in the purging in step A1 (purging).

### [Performing a Predetermined Number of Times]

A cycle of performing the above-described steps C1 to C3 non-simultaneously, that is, without synchronization is performed a predetermined number of times (1 times where 1 is an integer of 1 or more), whereby a second film, for example, a silicon carbonitride film (SiCN film) having a predetermined thickness and containing Si as a first element, N as a second element, and C as a third element can be formed on the surface of the member in the process container as a base. It is desirable that the above-mentioned cycle is repeated multiple times. That is, it is desirable that the thickness of the SiCN layer formed per cycle is set to be smaller than a desired film thickness, and the above-mentioned cycle is repeated multiple times until the thickness of a SiCN film formed by stacking the SiCN layers reaches the desired film thickness.

After the precoating is completed, the empty boat 217 is unloaded from the lower end of the manifold 209 to the outside of the reaction tube 203 (boat unloading).

### (3) Control Operation Performed in Second Film Formation

The first film formation and the second film formation described above may be performed consecutively in any order on the same wafer 200. For example, after performing the first film formation on a predetermined wafer 200, the second film formation may be consecutively performed on the same wafer 200. Further, for example, after performing the second film formation on a predetermined wafer 200, second film formation may be consecutively performed on the same wafer 200.

Further, the first film formation and the second film formation described above may be consecutively performed on another wafers 200 in an arbitrary order. For example, after performing the first film formation on a predetermined wafer 200, the second film formation may be performed on another wafer 200 different from the predetermined wafer 200. Further, after performing the second film formation on a predetermined wafer 200, second film formation may be performed on another wafer 200 different from the predetermined wafer 200.

In any case, when the first film formation is performed, the inside of the process container comes into a state in which the first film adheres to the outermost surface of the members in the process container (e.g., the inner wall of the reaction tube 203, the surface of the boat 217, etc.) (hereinafter, this state is also referred to as first state). Further, when the second film formation is performed, the inside of the process container comes into a state in which the second film adheres to the outermost surface of the member in the process container (hereinafter, this state is also referred to as second state).

In addition, when the first film and the second film are deposited and accumulated in the process container by performing the first film formation and the second film formation, that may be a case that a process (cleaning) of supplying an etching gas or the like into the process container and removing the film accumulated in the process container is performed. When the cleaning is performed, the inside of the process container comes into a state in which a cleaned surface is exposed on the surface of the member in the process container (hereinafter, this state is also referred to as third state). After the cleaning is performed, the first film formation and the second film formation are restarted.

According to the inventors' intensive research, it was found that when the second film formation is performed in the first state, there may occur a phenomenon in which the thickness of the second film formed on the wafer 200 becomes smaller or larger, compared with a case where the second film formation is performed in the second state (hereinafter, this phenomena will also be referred to as a film thickness variation phenomenon). For example, when the second film formation is performed in the first state in which a binary film such as a SiN film as the first film adheres to the outermost surface of the member in the process container, there may occur a film thickness variation phenomenon in which the thickness of the second film formed on the wafer 200 becomes larger, compared with a case where the second film formation is performed in the second state in which a ternary film such as a SiCN film as the second film adheres to the outermost surface of the member in the process container.

In addition, when the second film formation is performed in the third state, there may occur a phenomenon in which the thickness of the second film formed on the wafer 200 becomes smaller, compared with a case where the second film formation is performed in the second state (hereinafter, this phenomena will also be referred to as a film thickness variation phenomenon after cleaning).

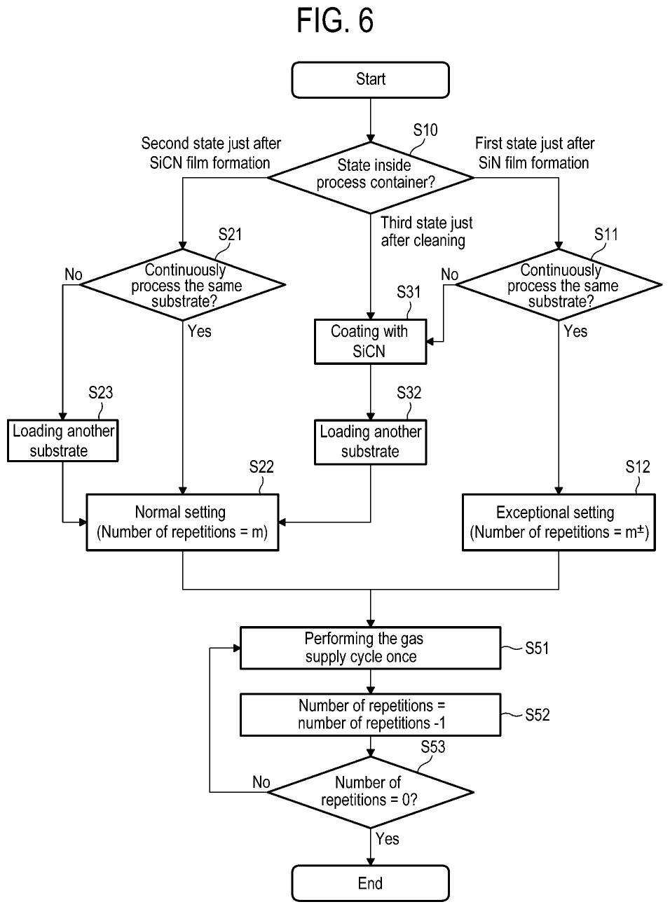

To cope with these problems, in the present embodiment, when performing the second film formation, various controls shown in FIG. 6 are performed according to the states (first to third states) in the process container.

Specifically, when the second film formation is performed in the second state in which the second film adheres to the outermost surface of the member in the process container (in the case of “second state” in S10), a process (normal setting) of setting the number of repetitions of the cycle to a predetermined number m is performed (S22) and then the repetition of the cycle is started. That is, when performing the second film formation in the second state in which the second film adheres to the outermost surface of the member in the process container, the cycle is performed m times.

Further, when the second film formation is performed in the first state in which the first film adheres to the outermost surface of the member in the process container (in the case of “first state” in S10), a process (exceptional setting) of setting the number of repetitions of the cycle to m^{±} (where m^{±} is an integer that is different from m) is performed (S12) and then the repetition of the cycle is started, or the above-described precoating (S31) for forming the second film on the outermost surface of the member in the process container and the normal setting (S22) are performed and then the repetition of the cycle is started. That is, when the second film formation is performed in the first state in which the first film adheres to the outermost surface of the member in the process container, the cycle is performed m^{±} times (where m^{±} is an integer that is different from m), or the cycle is performed m times after performing a precoating process of forming the second film on the outermost surface of the member in the process container. When a SiN film as the first film is formed in the first film formation and a SiCN film as the second film is formed in the second film formation, the number of repetitions of the cycle is set to m⁻ (where m⁻ is an integer that is less than m) in the exceptional setting.

Further, when the second film formation is performed in the third state in which the cleaned surface is exposed on the surface of the member in the process container (in the case of “third state” in S10), the precoating (S31) and the normal setting (S22) are performed and then the repetition of the cycle is started.

In either case, the cycle is performed once (S51), the number of repetitions set in S22 or S12 is decremented (S52), and it is determined whether the number of repetitions after the decrement is zero. If the number of repetitions after the decrement is not zero (No in S53), S51 and S52 are repeated. If the number of repetitions after the decrement becomes zero (Yes in S53), the repetition of the cycle is terminated.

As a result of the above-described control, in the present embodiment, when the first film formation is performed on a predetermined wafer 200 and then the second film formation is consecutively performed on the same wafer 200, that is, when the second film formation is performed on the same wafer 200 in the first state, exceptional setting is performed and then the repetition of the cycle is started (see S10→S11→S12→S51 to S53 in FIG. 6).

Further, in the present embodiment, when the second film formation is performed on a predetermined wafer 200 and then the second film formation is consecutively performed on the same wafer 200, that is, when the second film formation is performed on the same wafer 200 in the second state, normal setting is performed and then the repetition of the cycle is started (see S10→S21→S22→S51 to S53 in FIG. 6).

Further, in the present embodiment, when the first film formation is performed on a predetermined wafer 200 and then the second film formation is performed on another wafer 200 different from the predetermined wafer 200, that is, when the second film formation is performed on another wafer 200 in the first state, precoating and normal setting are performed and then the repetition of the cycle is started (see S10→S11→S31→S32→S22→S51 to S53 in FIG. 6).

Further, in the present embodiment, when the second film formation is performed on a predetermined wafer 200 and then the second film formation is performed on another wafer 200 different from the predetermined wafer 200, that is, when the second film formation is performed on another wafer 200 in the second state, normal setting is performed and then the repetition of the cycle is started (see S10→S21→S23→S22→S51 to S53 in FIG. 6).

### (4) Effects of the Present Embodiment

According to the present embodiment, one or more of the following effects may be obtained.

(a) when the second film formation is performed in the first state, there may occur a film thickness variation phenomenon in which the thickness of the second film formed on the wafer 200 varies unlike the case where the second film formation is performed in the second state. To cope with this problem, in the present embodiment, when the second film formation is performed in the second state, the normal setting for setting the number of repetitions of the cycle to m is performed and then the repetition of the cycle is started. When the second film formation is performed in the first state, the exceptional setting for setting the number of repetitions of the cycle to m^{±} (where m^{±} is an integer that is different from m) is performed and then the repetition of the cycle is started, or the precoating for forming the second film on the outermost surface of the member in the process container and the normal setting are performed and then the repetition of the cycle is started. In other words, when the second film formation is performed in the second state, the cycle is performed m times. When the second film formation is performed in the first state, the cycle is performed m^{±} times (where m^{±} is an integer that is different from m), or the cycle is performed after performing a precoating process of forming the second film on the outermost surface of the member in the process container. Thus, even when the second film formation is performed in the first state or the second film formation is performed in the second state, the thickness of the second film formed on the wafer 200 can be kept constant at all times.

For example, when the second film formation is performed in the first state in which a binary film such as a SiN film as the first film adheres to the outermost surface of the member in the process container, there may occur a film thickness variation phenomenon in which the thickness of the second film formed on the wafer 200 becomes larger, compared with a case where the second film formation is performed in the second state in which a ternary film such as a SiCN film as the second film adheres to the outermost surface of the member in the process container. To cope with this problem, in the present embodiment, in the exceptional setting, the number of repetitions of the cycle is set to m⁻ (where m⁻ is an integer that is less than m). Thus, even when the second film formation is performed in the first state or the second film formation is performed in the second state, the thickness of the second film formed on the wafer 200 can be kept constant at all times.

(b) When the first film formation is performed on a predetermined wafer 200 and then the second film formation is consecutively performed on the wafer 200, the second film formation, which is performed after the first film formation, is performed in the first state. Therefore, the film thickness variation phenomenon described above is likely to occur. On the other hand, by starting the repetition of the cycle after performing the above-described exceptional setting in the second film formation performed after the first film formation as in the present embodiment, the thickness of the second film formed on the wafer 200 can be kept constant at all times. Further, in this case, since the precoating accompanied by the unloading and loading of the wafer 200 is not performed, it is possible to avoid a decrease in substrate processing productivity.

(c) When the second film formation is performed on a predetermined wafer 200 and then the second film formation is consecutively performed on the wafer 200, the later second film formation is performed in the second state. As a result, the film thickness variation phenomenon described above is less likely to occur. Therefore, in this case, as in the present embodiment, the repetition of the cycle is started after performing the normal setting in the later second film formation, whereby the thickness of the second film formed on the wafer 200 can be kept constant at all times.

(d) When the first film formation is performed on a predetermined wafer 200 and then the second film formation is performed on a wafer 200 different from the predetermined wafer 200, the second film formation, which is performed after the first film formation, is performed in the first state. Therefore, the film thickness variation phenomenon described above is likely to occur. On the other hand, according to the present embodiment, the repetition of the cycle is started after performing the precoating and the normal setting in the second film formation, which is performed after the second film formation, whereby the thickness of the second film formed on the wafer 200 can be kept constant at all times. Further, in this case, since the exceptional setting is not performed, it is possible to simplify the control program and reduce the manufacturing cost of the substrate processing apparatus.

(e) When the second film formation is performed on a predetermined wafer 200 and then the second film formation is performed on a wafer 200 different from the predetermined wafer 200, the later second film formation is performed in the second state. Therefore, the film thickness variation phenomenon described above is less likely to occur. On the other hand, according to the present embodiment, the repetition of the cycle is started after performing the normal setting in the later second film formation, whereby the thickness of the second film formed on the wafer 200 can be kept constant at all times.

(f) When the second film formation is performed in the third state, the repetition of the cycle is started after performing the precoating and the normal setting. Therefore, the film thickness variation phenomenon after cleaning is less likely to occur. The thickness of the second film formed on the wafer 200 can be kept constant at all times.

(g) The precoating is performed in a state in which the wafer 200 does not exist in the process container. Therefore, it is possible to avoid the influence of the precoating on the wafer 200. In the precoating, just like the second film formation, by repeating the cycle of supplying the second processing gas into the process container, the processing gas and the control program can be shared by the precoating and the second film formation, and the manufacturing cost of the substrate processing apparatus can be reduced.

### Other Embodiments of the Present Disclosure

One embodiment of the present disclosure has been specifically described above. However, the present disclosure is not limited to the embodiment described above, and may be modified in various ways without departing from the scope of the present disclosure.

In the above-described mode, there has been described the example where the exceptional setting for setting the number of repetitions of the cycle to m⁻ (where m⁻ is an integer that is less than m) is performed to avoid the film thickness variation phenomenon in which the film thickness of the second film becomes large if the second film formation is performed when the inside of the process container is in the first state. However, the present disclosure is not limited thereto. For example, when there occurs a phenomenon in which the film thickness of the second film becomes small if the second film formation is performed when the inside of the process container is in the first state, exceptional setting for setting the number of repetitions of the cycle to m⁺ (where m⁺ is an integer that is more than m) may be performed to avoid occurrence of the above-mentioned phenomenon. Also in this case, the same effects as those of the above-described embodiment and modifications can be obtained.

In the above-described embodiment, there has been described the example where the precoating and the normal setting for setting the number of repetitions of the cycle to m are performed to avoid the film thickness variation phenomenon in which the film thickness of the second film becomes small if the second film formation is performed when the inside of the process container is in the third state. However, the present disclosure is not limited thereto. For example, if the second film formation is performed when the inside of the process container is in the third state, exceptional setting for setting the number of repetitions of the cycle to m⁺ (where m⁺ is an integer that is more than m) is performed without performing the precoating and the normal setting. Therefore, it is possible to avoid occurrence of the above-mentioned phenomenon. Also in this case, the same effects as those of the above-described embodiment and modifications can be obtained.

In the above-described embodiment, there has been described the case where the cycle of non-simultaneously supplying the precursor and the nitriding agent is performed a predetermined number of times (one or more times) in the first film formation. However, the present disclosure is not limited thereto. For example, the present disclosure may be suitably applied to a case where a cycle of simultaneously supplying a precursor and a nitriding agent is performed a predetermined number of times (one or more times) in the first film formation. Also in this case, the same effects as those of the above-described embodiment and modifications can be obtained.

In the above-described embodiment, there has been described the case where the cycle of non-simultaneously supplying the precursor, the N- and C-containing gas, and the nitriding agent is performed in the second film formation. However, the present disclosure is not limited thereto. For example, as in the film formation sequences described below, in the second film formation, a cycle of non-simultaneously supplying the precursor and the N- and C-containing gas may be performed. Further, in the second film formation, a cycle of non-simultaneously performing a step of supplying the precursor and a step of simultaneously supplying the N- and C-containing gas and the nitriding agent may be performed. Moreover, as the precursor, a gas containing Si and C such as a 1,1,2,2-tetrachloro-1,2-dimethyldisilane ((CH₃)₂Si₂Cl₄, abbreviation: TCDMDS) gas, a 1,2-dichloro-1,1,2,2-tetramethyldisilane ((CH₃)₄Si₂Cl₂, abbreviation: DCTMDS) gas, a bis(trichlorosilyl)methane ((SiC₁₃)₂CH₂, abbreviation: BTCSM) gas, or the like may be used, and a cycle of non-simultaneously supplying the precursor and the nitriding agent may be performed. In addition, a cycle of non-simultaneously supplying a precursor, a carbon (C)-containing gas such as a propylene (C₃H₆) gas or the like, and a nitriding agent may be performed.

(precursor→N- and C-containing gas)×m

(precursor→N- and C-containing gas+nitriding agent)×m

(precursor containing Si and C→nitriding agent)×m

(precursor→C-containing gas→nitriding agent)×m

The processing procedures and processing conditions in each step may be the same as the processing procedures and processing conditions in each step of the above-described embodiment. Even in these cases, the same effects as those of the above-described embodiment and modifications can be obtained.

In the above-described embodiment, there has been described the case where in the precoating, the second film is formed by using the outermost surface of the member in the process container as a base. However, the present disclosure is not limited thereto. For example, in the precoating, after forming the first film on the outermost surface of the member in the process container, the second film may be stacked on the first film. Further, in the precoating, after the first film is formed on the outermost surface of the member in the process container, the first film may be modified into the second film. Even in these cases, the same effects as those of the above-described embodiment and modifications can be obtained.

In the above-described embodiment, there has been described the case where each of the first film and the second film contains Si as a main element. However, the present disclosure is not limited thereto. For example, the present disclosure may be suitably applied to a case where each of the first film and the second film contains, as a main element, a metal element such as titanium (Ti), zirconium (Zr), hafnium (Hf), tantalum (Ta), niobium (Nb), molybdenum (Mo), tungsten (W), yttrium (Y), strontium (Sr), lanthanum (La), ruthenium (Ru), aluminum (Al) or the like. Even in these cases, the same effects as those of the above-described embodiment and modifications can be obtained.

It is desirable that the recipe used for each process are prepared separately according to the processing contents and are stored in the memory 121c via an electric communication line or an external memory 123. When starting each process, it is desirable that the CPU 121a properly selects an appropriate recipe from a plurality of recipes stored in the memory 121c according to the contents of the process. This makes it possible to form films of various film types, composition ratios, film qualities and film thicknesses with high reproducibility in one substrate processing apparatus. In addition, the burden on an operator can be reduced, and each process can be quickly started while avoiding operation errors.

The above-described recipes are not limited to the newly-prepared ones, but may be prepared by, for example, changing the existing recipes already installed in the substrate processing apparatus. In the case of changing the recipes, the recipes after the change may be installed in the substrate processing apparatus via an electric communication line or a recording medium in which the recipes are recorded. In addition, the input/output device 122 provided in the existing substrate processing apparatus may be operated to directly change the existing recipes already installed in the substrate processing apparatus.

In the above-described embodiment, there has been described an example in which a film is formed using a batch type substrate processing apparatus for processing a plurality of substrates at a time. The present disclosure is not limited to the above-described embodiment, but may be suitably applied to, for example, a case where a film is formed using a single-wafer type substrate processing apparatus for processing one or several substrates at a time. Furthermore, in the above-described embodiment, there has been described an example in which a film is formed using a substrate processing apparatus having a hot wall type process furnace. The present disclosure is not limited to the above-described embodiment, but may also be suitably applied to a case where a film is formed using a substrate processing apparatus having a cold wall type process furnace.

Even in the case of using these substrate processing apparatuses, each process may be performed under the same processing procedures and processing conditions as those in the above-described embodiment and modifications, and the same effects as those of the above-described embodiment and modifications may be obtained.

In addition, the above-described embodiment and modifications may be used in combination as appropriate. The processing procedures and processing conditions at this time may be the same as, for example, the processing procedures and processing conditions of the above-described embodiment.

According to the present disclosure in some embodiments, it is possible to provide a technique capable of improving the controllability of the thickness of a film formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) forming a first film having a predetermined composition on a first substrate by supplying a first processing gas to the first substrate accommodated in a process container; and
(b) forming a second film having a composition different from the composition of the first film on the first substrate or a second substrate different from the first substrate by performing a cycle including a supply of a second processing gas to the first substrate or the second substrate which is accommodated in the process container,
wherein when performing (b) in a second state in which the second film adheres to an outermost surface of a member in the process container, the cycle is performed a predetermined m times, where m is an integer of 1 or more, and
wherein when performing (b) in a first state in which the first film adheres to the outermost surface of the member in the process container, the cycle is performed m^{±} times, where m^{±} is an integer that is different from m, or the cycle is performed the m times after performing a precoating process of forming the second film on the outermost surface of the member in the process container.

2. The method of claim 1, wherein the act of performing the cycle them times is executed based on a normal setting process of setting the number of repetitions of the cycle to m, and
wherein the act of performing the cycle the m^{±} times is executed based on an exceptional setting process of setting the number of repetitions of the cycle to m^{±}.

3. The method of claim 2, wherein when (a) is performed on the first substrate and then (b) is consecutively performed on the first substrate, the act of performing the cycle is started after the exceptional setting process is performed.

4. The method of claim 2, wherein when (b) is performed on the first substrate and then (b) is consecutively performed on the first substrate, the act of performing the cycle is started after the normal setting process is performed.

5. The method of claim 2, wherein when (a) is performed on the first substrate and then (b) is performed on the second substrate, the act of performing the cycle is started after the precoating process and the normal setting process are performed.

6. The method of claim 2, wherein when (b) is performed on the first substrate and then (b) is performed on the second substrate, the act of performing the cycle is started after the normal setting process is performed.

7. The method of claim 2, wherein when (b) is performed in a third state in which cleaning is performed on a surface of the member in the process container and a cleaned surface is exposed, the act of performing the cycle is started after the precoating process and the normal setting process are performed.

8. The method of claim 1, wherein in the precoating process, the cycle including the supply of the second processing gas into the process container is performed in a state in which no substrate is present in the process container.

9. The method of claim 1, wherein in (a), a film containing a first element and a second element is formed as the first film,
wherein in (b), a film containing the first element, the second element, and a third element is formed as the second film, and
wherein, when (b) is performed in the first state, (b) is performed by setting the number of repetitions of the cycle to m⁻, where m⁻ is an integer that is less than m.

10. The method of claim 9, wherein in (a), a silicon nitride film is formed as the first film, and wherein in (b), a silicon carbonitride film is formed as the second film.

11. The method of claim 1, wherein when performing (b) in the first state, (b) is performed by setting the number of repetitions of the cycle to m^{±}.

12. The method of claim 1, wherein when performing (b) in the first state, (b) is performed by setting the number of repetitions of the cycle to m⁺, where m⁺ is an integer that is more than m.

13. The method of claim 2, wherein in the exceptional setting process, the number of repetitions of the cycle is set to m⁺, where m⁺ is an integer that is more than m.

14. The method of claim 1, wherein when performing (b) in a third state in which cleaning is performed on a surface of the member in the process container and a cleaned surface is exposed, (b) is performed by setting the number of repetitions of the cycle to m⁺, where m⁺ is an integer that is more than m.

15. The method of claim 2, wherein when performing (b) in a third state in which cleaning is performed on a surface of the member in the process container and a cleaned surface is exposed, the act of performing the cycle is started after performing the exceptional setting process of setting the number of repetitions of the cycle to m⁺, where m⁺ is an integer that is more than m.

16. A method of manufacturing a semiconductor device, comprising the method of claim 1.

17. A substrate processing apparatus, comprising:
a process container configured to accommodate a substrate;
a processing gas supply system configured to supply a first processing gas and a second processing gas into the process container; and
a controller configured to be capable of controlling the processing gas supply system to perform:
(a) forming a first film having a predetermined composition on a first substrate by supplying the first processing gas to the first substrate accommodated in the process container; and
(b) forming a second film having a composition different from the composition of the first film on the first substrate or a second substrate different from the first substrate by performing a cycle including a supply of the second processing gas to the first substrate or the second substrate which is accommodated in the process container,
wherein when performing (b) in a second state in which the second film adheres to an outermost surface of a member in the process container, the cycle is performed a predetermined m times, where m is an integer of 1 or more, and
wherein when performing (b) in a first state in which the first film adheres to the outermost surface of the member in the process container, the cycle is performed m^{±} times, where m^{±} is an integer that is different from m, or the cycle is performed the m times after performing a precoating process of forming the second film on the outermost surface of the member in the process container.

18. A non-transitory computer-readable recording medium storing a program that causes, by a computer, a substrate processing apparatus to perform a process comprising:
(a) forming a first film having a predetermined composition on a first substrate by supplying a first processing gas to the first substrate accommodated in a process container; and
(b) forming a second film having a composition different from the composition of the first film on the first substrate or a second substrate different from the first substrate by performing a cycle including a supply of a second processing gas to the first substrate or the second substrate which is accommodated in the process container,
wherein when performing (b) in a second state in which the second film adheres to an outermost surface of a member in the process container, the cycle is performed a predetermined m times, where m is an integer of 1 or more, and
wherein when performing (b) in a first state in which the first film adheres to the outermost surface of the member in the process container, the cycle is performed m^{±} times, where m^{±} is an integer that is different from m, or the cycle is performed the m times after performing a precoating process of forming the second film on the outermost surface of the member in the process container.
